(19) United States
(12) Patent Application Publication
(10) Pub. No.: US 2025/0167754 A1
(43) Pub. Date: May 22, 2025

(54) RESONATOR

(71) Applicant: TXC Corporation, Taipei City (TW)

(72) Inventors: Zong-De Lin, Taipei City (TW); Tzu-Hsiu Peng, Taipei City (TW)

(73) Assignee: TXC Corporation, Taipei City (TW)

(21) Appl. No.: 18/590,952

(22) Filed: Feb. 29, 2024

(30) Foreign Application Priority Data
Nov. 22, 2023 (TW) 112145211

(51) Int. Cl. H03H 9/02; H03H 9/10; H03H 9/13; H03H 9/19

(52) U.S. Cl. CPC H03H 9/02086; H03H 9/1021; H03H 9/132; H03H 9/19

(57) ABSTRACT

A resonator including a vibration plate, a first electrode, and a second electrode is provided. The vibration plate has a first surface and a second surface opposite to the first surface. The first electrode is disposed on the first surface, and the second electrode is disposed on the second surface. At least one of the first electrode and the second electrode has a plurality of openings. The openings are pairwise distributed. Each pair of openings are symmetrically distributed with respect to a geometric center of an electrode which the openings belong to. All the openings do not contact with an edge of the electrode which the openings belong to.

### CROSS-REFERENCE TO RELATED APPLICATION

This application claims the priority benefit of Taiwan application serial no. 112145211, filed on Nov. 22, 2023. The entirety of the above-mentioned patent application is hereby incorporated by reference herein and made a part of specification.

### BACKGROUND

### Technical Field

The invention generally relates to an electronic device and, in particular, to a resonator.

### Description of Related Art

The resonator is an electronic device that utilizes the piezoelectric properties of the material and the natural resonance frequency of the material, and the quartz crystal is a common piezoelectric material used in the resonator. In a conventional resonator, there are electrodes on both sides of the piezoelectric material. When a voltage difference is applied between the two electrodes, the piezoelectric material will deform due to the inverse piezoelectric effect. Then when the voltage difference is removed, the piezoelectric material will continue to vibrate, and due to the piezoelectric effect, the voltage between the two electrodes will change with the vibration, so that the two electrodes can output voltage signals.

Due to physical limitations, the adjacent frequencies of the main vibration shape mode of piezoelectric material (such as thickness shear vibration mode) are often accompanied by spurious modes such as a flexural mode and a face shear mode, that is, unwanted modes. If the frequency difference between the spurious mode and the main vibration shape mode is too close, the spurious mode will couple with the main vibration shape mode, thereby affecting product characteristics, especially in automotive applications or even miniaturized automotive applications that have a wide operating temperature range, in which the spurious mode is even more of a thorny problem.

### SUMMARY

The invention provides a resonator that can effectively suppress spurious modes.

An embodiment of the invention proposes a resonator, including a vibration plate, a first electrode and a second electrode. The vibration plate has a first surface and a second surface opposite to each other. The first electrode is disposed on the first surface, and the second electrode is disposed on the second surface. At least one of the first electrode and the second electrode has a plurality of openings. These openings are pairwise distributed. Each pair of openings is symmetrically distributed with respect to the geometric center of the electrode to which the openings belong, and all of these openings have no contact with the edge of the electrode to which the openings belong.

In the resonator of the embodiment of the invention, at least one of the first electrode and the second electrode has a plurality of openings, these openings are pairwise distributed, each pair of openings is symmetrically distributed with respect to the geometric center of the electrode to which the openings belong, and all these openings do not contact the edge of the electrode to which the openings belong. Therefore, the resonator of the embodiment of the invention can effectively suppress spurious modes.

### BRIEF DESCRIPTION OF THE DRAWINGS

FIG. 1A is a schematic cross-sectional view of an embodiment of the resonator of the invention.

FIG. 1B is a three-dimensional schematic diagram of the vibration plate, first electrode and adhesive in FIG. 1A.

FIGS. 2A to 2D are schematic top views of the vibration plate and first electrode of four other embodiments of the invention.

FIGS. 3A to 3E are schematic top views of the vibration plate and first electrode of five other embodiments of the invention.

FIG. 4 is a three-dimensional schematic diagram of the vibration plate, first electrode and adhesive of another embodiment of the invention.

### DESCRIPTION OF THE EMBODIMENTS

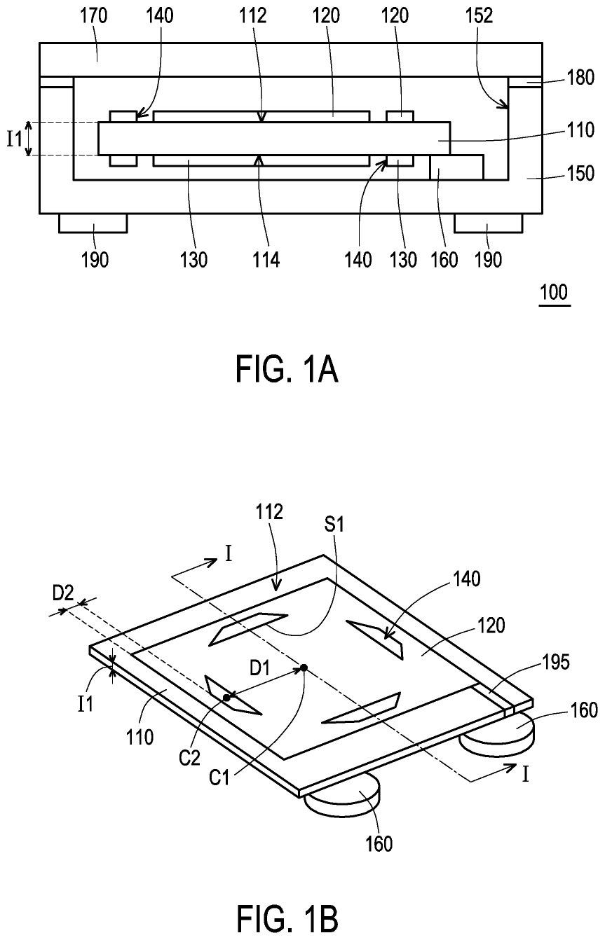

FIG. 1A is a schematic cross-sectional view of the resonator of an embodiment of the invention, and FIG. 1B is a schematic three-dimensional view of the vibration plate, first electrode and adhesive in FIG. 1A, wherein the cross-section of the vibration plate, first electrode and second electrode in FIG. 1A is a cross-section cut along line I-I in FIG. 1B. Please refer to FIG. 1A and FIG. 1B. The resonator 100 of this embodiment includes a vibration plate 110, a first electrode 120 and a second electrode 130. The vibration plate 110 has a first surface 112 and a second surface 114 opposite to each other. The first electrode 120 is disposed on the first surface 112, and the second electrode 130 is disposed on the second surface 114. In this embodiment, the vibration plate 110 is made of piezoelectric material. For example, the vibration plate 110 is a quartz plate. In addition, each of the first electrode 120 and the second electrode 130 is an electrode layer.

The first electrode 120 and the second electrode 130 are suitable for being applied a voltage difference. When there is a voltage difference between the first electrode 120 and the second electrode 130, the vibration plate 110 will be deformed due to the inverse piezoelectric effect. Then when the voltage difference is removed, the vibration plate 110 will continue to vibrate, and due to the piezoelectric effect, the voltage between the first electrode 120 and the second electrode 130 will change with this vibration, so that the first electrode 120 and the second electrode 130 can output voltage signal.

In the resonator 100 of this embodiment, at least one of the first electrode 120 and the second electrode 130 has a plurality of openings 140 (FIG. 1A takes the first electrode 120 and the second electrode 130 both having a plurality of openings 140 as an example). The openings 140 of the first electrode 120 expose a part of the first surface 112 of the vibration plate 110, and the openings 140 of the second electrode 130 expose the second surface 114 of the vibration plate 110. These openings 140 are pairwise distributed, each pair of openings 140 is symmetrically distributed relative to the geometric center C1 of the electrode to which the openings 140 belong, and all of these openings 140 have no contact with the edge of the electrode to which the openings 140 belong. In this embodiment, the area of these openings 140 accounts for less than or equal to 30% of the area of the electrode to which the openings 140 belong, the distance D1 between the geometric center C2 of each opening 140 and the geometric center C1 of the corresponding electrode (i.e. the electrode to which the openings 140 belong) is greater than or equal to the interval I1 between the first electrode 120 and the second electrode 130 (that is, the thickness of the main vibration zone of the vibration plate 110), and the distance D2 between each opening 140 and the edge of the electrode to which the openings 140 belong is greater than or equal to the interval I1 between the first electrode 120 and the second electrode 130. Therefore, the resonator 100 of this embodiment can effectively suppress spurious modes. When the area of these openings 140 accounts for less than or equal to 30% of the area of the electrode to which the openings 140 belong, the spurious mode (i.e. unwanted vibration modes such as a flexural mode and a face shear mode) can be effectively suppressed without damaging the main vibration shape mode (i.e., the thickness shear vibration mode). In addition, the electrode of the resonator 100 of this embodiment has an even number of openings 140 that run through the electrode and are not connected to each other, so the spurious modes can be effectively suppressed. In addition, the distance D1 between the geometric center C2 of each opening 140 and the geometric center C1 of the corresponding electrode is greater than or equal to the interval I1 between the first electrode 120 and the second electrode 130 (that is, the thickness of the main vibration zone of the vibration plate 110), and the distance D2 between each opening 140 and the edge of the electrode to which the openings 140 belong is greater than or equal to the interval I1 between the first electrode 120 and the second electrode 130, which can reduce the main vibration zone of the vibration plate 110 from being affected by the openings 140, thereby increasing the vibration intensity of the thickness shear vibration mode, and effectively suppressing the spurious modes.

In an embodiment, the distance D1 between the geometric center C2 of each opening 140 and the geometric center C1 of the corresponding electrode is greater than or equal to 5 times the interval I1 between the first electrode 120 and the second electrode 130 (that is, the thickness of the main vibration zone of the vibration plate 110).

In this embodiment, the distances D1 from the geometric center C2 of the two openings 140 in each pair of openings 140 or the geometric center C2 of all these openings 140 to the geometric center C1 of the corresponding electrode are the same as each other, which can improve the vibration intensity of the thickness shear vibration mode. Furthermore, in this embodiment, these openings 140 are not connected to each other.

In this embodiment, both the first electrode 120 and the second electrode 130 have the openings 140, and the shapes and positions of the openings 140 of the first electrode 120 correspond to the shapes and positions of the openings 140 of the second electrode 130 respectively. However, in other embodiments, one of the first electrode 120 and the second electrode 130 may have these openings 140, while the other one of the first electrode 120 and the second electrode 130 may not have these openings 140.

In this embodiment, the resonator 100 further includes a pedestal 150 and at least one adhesive 160 (FIG. 1B takes two adhesives 160 as an example). The vibration plate 110 is disposed on the pedestal 150, and is fixed on the pedestal 150 through the adhesives 160, for example. In this embodiment, the pedestal 150 has a recess 152, and the vibration plate 110 is disposed in the recess 152. In addition, in this embodiment, the resonator 100 further includes a top cover 170, which is disposed on the pedestal 150 and covers the vibration plate 110. In this embodiment, the top cover 170 can be disposed on the pedestal 150 through a seal ring 180.

In this embodiment, the resonator 100 further includes a plurality of pads 190, which are disposed below the pedestal 150. These pads 190 can be electrically connected to the first electrode 120 and the second electrode 130 through the conductive adhesives 160 and the conductive traces 195 respectively. In this way, an external voltage can be applied to the pads 190 and changes in the output voltage of the pads 190 can be sensed.

In this embodiment, each opening 140 has at least one linear long side S1 (FIG. 1B takes one linear long side S1 as an example), which can smooth the vibration boundary to improve the vibration intensity of the thickness shear vibration mode. In this embodiment, these openings 140 are symmetrically distributed with respect to the geometric center C1 of the electrode to which the openings 140 belong as the symmetry point, at least two linear long sides S1 of any two symmetrical openings 140 (FIG. 1B takes two linearly opposite long sides S1 as an example) are parallel to each other, and linear long sides S1 of any two symmetrical openings 140 face each other. Such a design can further suppress spurious modes. In this embodiment, each opening 140 has no contact with the edge of the electrode to which the openings 140 belong, that is, there is a distance D2 between the opening 140 and the edge of the electrode to which the openings 140 belong. This design can reduce the loss of vibration energy and maintain the vibration intensity of the thickness shear vibration mode.

In this embodiment, any two symmetrical openings 140 are located on opposite sides of the corresponding electrode. FIG. 1B takes four openings 140 being located adjacent to the four sides of the corresponding electrode as an example. In addition, in this embodiment, each opening 140 is a quadrilateral opening. FIG. 1B takes a trapezoid opening as an example, but it can also be a rectangle or other shapes in other embodiments.

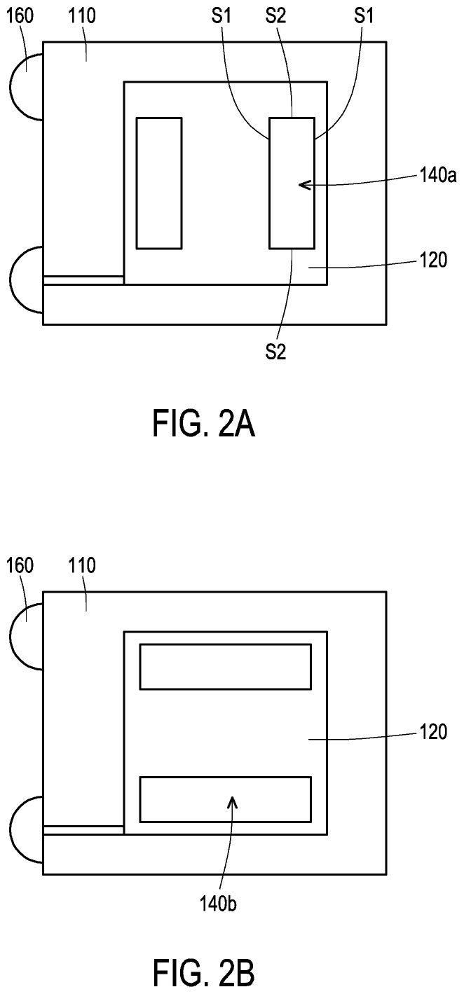

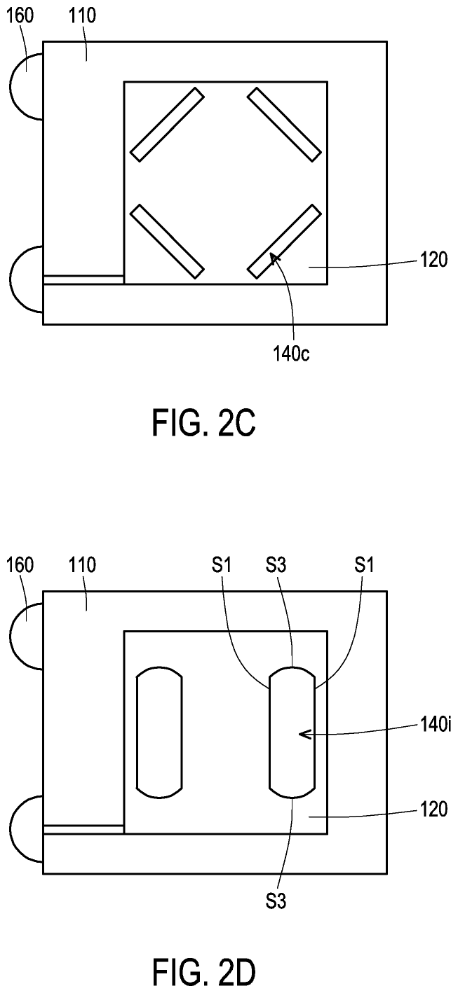

FIGS. 2A to 2D are schematic top views of the vibration plate and first electrode of four other embodiments of the invention. Please refer to FIG. 2A and FIG. 2B. In these two embodiments, the opening 140a and opening 140b are rectangles, but the opening 140a and opening 140b are arranged on different opposite sides of the corresponding electrode (the first electrode 120 is taken as an example in the figure). Please refer to FIG. 2C. In this embodiment, any two symmetrical openings 140c are located at opposite corners of the corresponding electrode (the first electrode 120 is taken as an example in the figure). In FIG. 2C, four openings 140c are located adjacent to the four corresponding corners of the electrode for example. Or, from another perspective, please refer to FIG. 2A. Each opening 140a has two linear long sides S1, and the two ends of the two linear long sides S1 are each connected by a straight side S2. Please refer to FIG. 2D. In this embodiment, each opening 140i has two linear long side S1, and the two ends of the two linear long side S1 are each connected by an arc side S3.

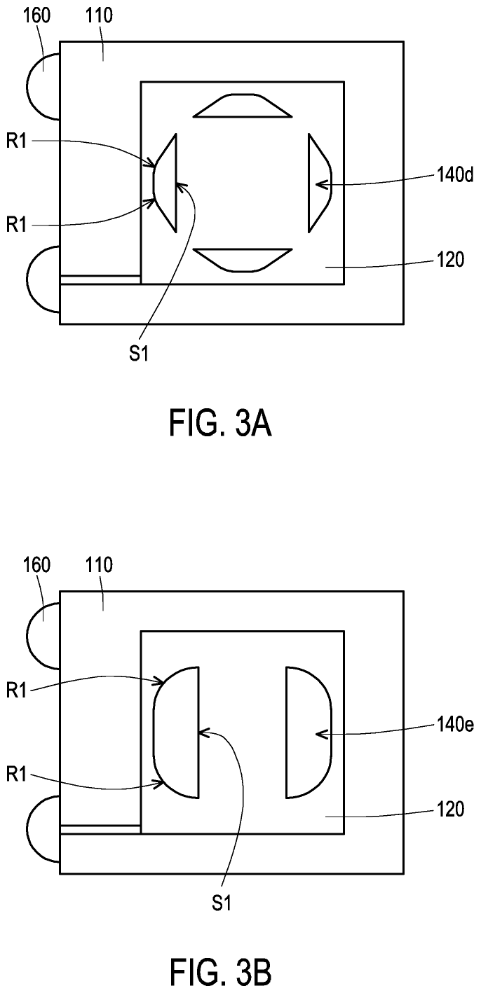

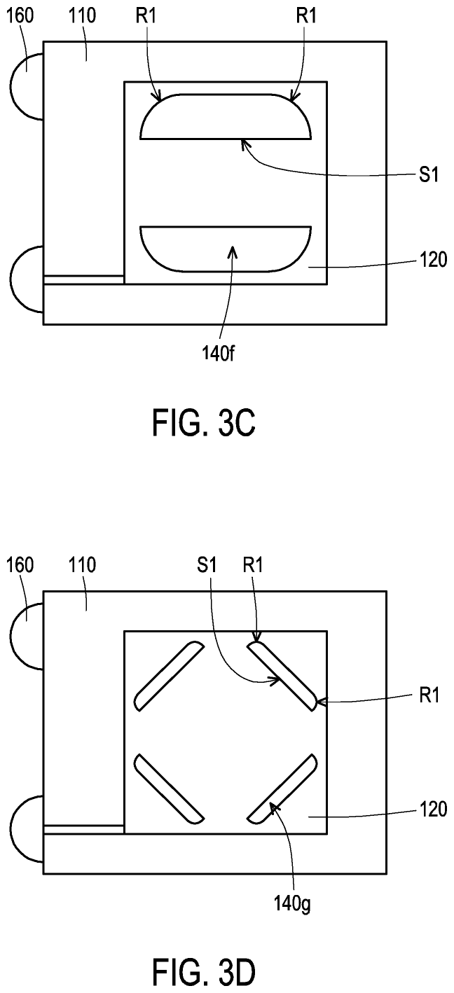

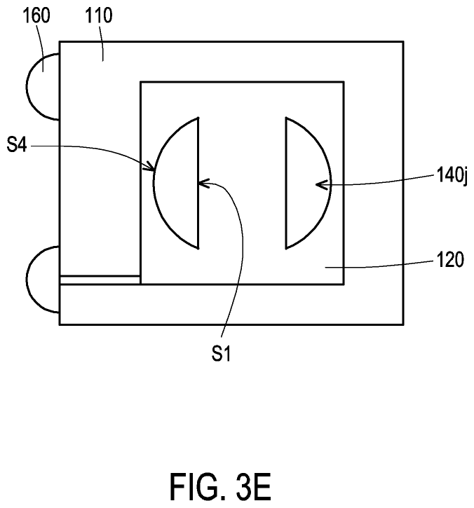

FIGS. 3A to 3E are schematic top views of the vibration plate and first electrode of five other embodiments of the invention. Please refer to FIG. 3A to FIG. 3D. In this embodiment, another side of each opening 140d, 140e, 140f, 140g opposite to the linear long side S1 has at least one round angle R1 (in the figure, two round angles R1 are taken as an example). In FIG. 3A, four openings 140d are respectively located adjacent to the four sides of the corresponding electrode (such as the first electrode 120). In FIG. 3B and FIG. 3C, the opening 140e and opening 140f are arranged on different opposite sides of the electrode (the first electrode 120 is taken as an example in the figure). In FIG. 3D, four openings 140g are located next to the four corners of the corresponding electrode. Please refer to FIG. 3E. In this embodiment, each opening 140j has a linear long side S1 and an arc side S4. The linear long side S1 and arc side S4 are respectively located on opposite sides of the opening 140j.

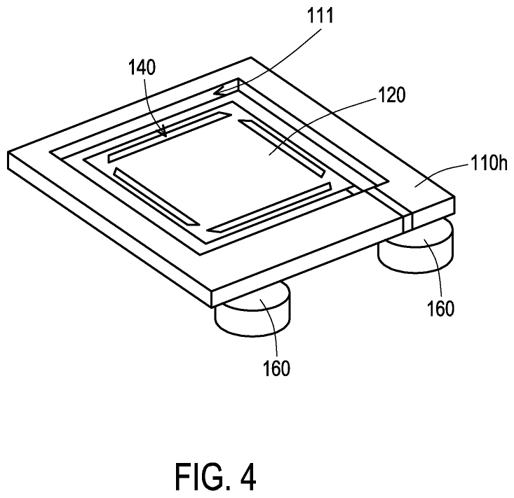

FIG. 4 is a three-dimensional schematic diagram of the vibration plate, first electrode and adhesive of another embodiment of the invention. Please refer to FIG. 4. The resonator of this embodiment is similar to the resonator 100 of FIGS. 1A and 1B. The difference between the two is that the vibration plate 110h of the resonator of this embodiment has a recess 111 on each of the upper and lower sides (as shown in FIG. 4, taking the recess 111 located on the upper side as an example), the first electrode 120 and the second electrode (located on the lower side blocked by the vibration plate 110h) are respectively located in these two recesses. The invention does not limit the form of the vibration plate. The vibration plate can be a flat plate as shown in FIG. 1B, a vibration plate 110h as shown in FIG. 4, or a vibration plate in other shapes.

To sum up, in the resonator of the embodiment of the invention, at least one of the first electrode and the second electrode has a plurality of openings. These openings are pairwise distributed, and each pair of openings is symmetrically distributed with respect to the geometric center of the electrode to which the openings belong, and all these openings have no contact with the edges of the electrode to which the openings belong. Therefore, the resonator of the embodiment of the invention can effectively suppress the spurious modes.

What is claimed is:

1. A resonator comprising:
a vibration plate having a first surface and a second surface opposite to each other;
a first electrode disposed on the first surface; and
a second electrode disposed on the second surface, wherein at least one of the first electrode and the second electrode has a plurality of openings, the openings are pairwise distributed, each pair of openings is symmetrically distributed with respect to the geometric center of an electrode to which the openings belong, and all the openings do not contact with an edge of the electrode to which the openings belong.

2. The resonator according to claim 1, wherein the distances from the respective geometric centers of two openings in each pair of openings or the geometric centers of all openings to the geometric center of the electrode to which the openings belong are the same as each other.

3. The resonator according to claim 1, wherein the openings are not connected to each other.

4. The resonator according to claim 1, wherein a distance between the geometric center of each opening and the geometric center of the electrode to which the openings belong is greater than or equal to an interval between the first electrode and the second electrode.

5. The resonator according to claim 1, wherein each opening has at least one linear long side.

6. The resonator according to claim 5, wherein each opening has two linear long sides, and two ends of the two linear long sides are each connected by an arc side or a straight side.

7. The resonator according to claim 5, wherein each opening has a linear long side and an arc side, and the linear long side and the arc side are respectively located on opposite sides of the opening.

8. The resonator according to claim 1, wherein an area of the openings accounts for less than or equal to 30% of an area of the electrode to which the openings belong.

9. The resonator according to claim 5, wherein the openings are symmetrically distributed with respect to the geometric center of the corresponding electrode as the symmetry point, at least two linear long sides of any two symmetrical openings are parallel to each other, and any two symmetrical openings have their linear long sides facing each other.

10. The resonator according to claim 9, wherein any two symmetrical openings are located on opposite sides of the corresponding electrode.

11. The resonator according to claim 9, wherein any two symmetrical openings are located at opposite corners of the corresponding electrode.

12. The resonator as according to claim 5, wherein another side of each opening opposite to the linear long side has at least a round angle.

13. The resonator according to claim 5, wherein each opening is a quadrilateral opening.

14. The resonator according to claim 1, wherein a distance between each opening and the geometric center of the corresponding electrode is greater than or equal to 5 times an interval between the first electrode and the second electrode.

15. The resonator according to claim 1, wherein both the first electrode and the second electrode have the openings, and shapes and positions of the openings of the first electrode respectively correspond to shapes and positions of the openings of the second electrode.
